(19) United States
(12) Patent Application Publication
(10) Pub. No.: US 2016/0270238 A1
(43) Pub. Date: Sep. 15, 2016

(54) ELECTRONIC CONTROL UNIT AND METHOD FOR ARRANGING ELECTRONIC COMPONENTS ON A CIRCUIT CARRIER AND FOR ELECTRICALLY CONNECTING SAID ELECTRONIC COMPONENTS TO A CIRCUIT CARRIER

(71) Applicants: CONTINENTAL TEVES AG & CO. OHG, Frankfurt (DE); CONTI TEMIC MICROELECTRONIC GMBH, Nürnberg (DE)

(72) Inventors: Lars Dalke, Manching (DE); Jürgen Gilb, Wehrheim (DE); Michael Weckerle, Wöllstadt (DE)

(21) Appl. No.: 15/028,608

(22) PCT Filed: Oct. 7, 2014
(86) PCT No.: PCT/EP2014/071476

§ 371 Date: Apr. 11, 2016

(30) Foreign Application Priority Data
Oct. 17, 2013 (DE) 10 2013 221 090.6

(51) Int. Cl. H05K 3/32; H05K 1/18; H05K 1/11

(52) U.S. Cl. CPC H05K 3/328; H05K 1/11; H05K 1/181; H05K 2201/1003

(57) ABSTRACT

An electronic control unit, in particular of a motor vehicle brake system, including at least one circuit carrier for electronic components. At least one electronic component has at least one electrical conductor. The electronic control unit is further distinguished in that the electrical conductor of the electronic component is connected to at least one contact element mechanically and in an electrically conductive manner and the contact element is connected to at least one contact point of the circuit carrier mechanically and in an electrically conductive manner, at least the mechanical and electrically conductive connection of the electrical conductor to the contact element being a connection established by ultrasonic welding. A method for arranging at least one electronic component on and electrically connecting the at least one electronic component to a circuit carrier of an electronic control unit is also disclosed.

### CROSS REFERENCE TO RELATED APPLICATIONS

This application is the U.S. National Phase Application of PCT International Application No. PCT/EP2014/071476, filed Oct. 7, 2014, which claims priority to German Patent Application No. 10 2013 221 090.6, filed Oct. 17, 2013, the contents of such applications being incorporated by reference herein.

### FIELD OF THE INVENTION

The present invention relates to an electronic control unit and to a method for arranging electronic components on a circuit carrier and for supplying electrical power to said electronic components.

### BACKGROUND OF THE INVENTION

As is known per se, electronic components are used in electronic control units, in particular motor vehicle control units, for example in order to already filter in the high-current path any interference introduced via an on-board vehicle power supply system. Since these components used for interference suppression are often exposed during operation to high currents, a solid design with large diameters of the electrical conductors associated with the components is necessary, whereby these conductors have a comparatively large spatial requirement and accordingly can be heavy. An arrangement and electrical connection of these components on the printed circuit board in a conventional reflow process, jointly with further SMD components, therefore is not practicable without significant additional effort, and therefore other joining methods are often used.

The ends or regions of the electrical conductors of these components to be contacted have here a high position tolerance, whereby direct contact with the circuit carrier is additionally complex. Corresponding contact points, for example contact openings or contact surfaces, of the printed circuit board are therefore not directly contacted without an alignment of the ends of the conductors. Layout requirements, which define the orientation and position of components on the circuit carrier, likewise determine the orientation and position of the contact points of the circuit carrier with the wired components. In the event of direct contact with the circuit carrier, the ends of the conductors would have to be bent in such a way that they contact the contact points of the circuit carrier, which in many cases is not practicable without considerable effort.

### SUMMARY OF THE INVENTION

An aspect of the invention provides a possibility for the arrangement and electrical contacting of electronic components which overcomes the aforementioned problems and can be produced as economically as possible.

An aspect of the invention describes an electronic control unit, in particular of a motor vehicle brake system, comprising at least one circuit carrier for electronic components, wherein at least one electric component has at least one electrical conductor and is further characterized in that the electrical conductor of the electronic component is connected to at least one contact element mechanically and in an electrically conductive manner and the contact element is connected to at least one contact point of the circuit carrier mechanically and in an electrically conductive manner, wherein at least the mechanical and electrically conductive connection of the electrical conductor to the contact element is a connection established by means of ultrasonic welding.

The contact element thus serves advantageously as an adapter between the electronic component and the contact point of the circuit carrier, whereby, with appropriate structural design of the contact element in combination with the accuracy of the ultrasonic welding, a tolerance compensation is made possible and a high precision of the positioning of the contact element on the circuit carrier is attained. This is advantageous in particular for the assembly process of the component, since a prior orientation of the conductor, with respect to the contact points of the circuit carrier, can be omitted. With appropriate structural design of the contact elements, contact points distributed over an extensive area of the circuit carrier can be contacted. Due to the ultrasonic welding, disadvantages of other adjoining methods, such as a high heating of the assemblies to be connected, are additionally avoided.

Electrical contact produced in this way advantageously has a low electrical resistance alongside high mechanical strength. The ultrasonic welding method can be implemented economically, since the equipment investment costs are relatively low and no additional welding materials are necessary. For mass production, it is additionally particularly advantageous that very short cycle times can be attained.

In accordance with a preferred embodiment of the invention the contact element and/or the electrical conductor of the electronic component are embodied such that the electronic component is distanced from the circuit carrier in such a way that further electronic components, in particular SMD components, can be arranged in a region between the circuit carrier and the electronic component.

A larger number of components or a higher packing density can thus be attained advantageously on the circuit carrier.

The contact element is particularly preferably formed as a press-in contact, which comprises at least one press-in region, which is pressed into at least one contact point of the circuit carrier formed as a contact opening.

An aspect of the invention also describes a method for arranging at least one electronic component on and electrically connecting said at least one electronic component to a circuit carrier of an electronic control unit, in particular a control unit for a motor vehicle brake system, which is characterized in that at least one electrical conductor comprised by the electronic component is connected to at least one contact element mechanically and in an electrically conductive manner and the contact element is connected to at least one contact point of the circuit carrier mechanically and in an electrically conductive manner, wherein at least the mechanical and electrically conductive connection of the electrical conductor of the electronic component to the contact element is established by means of ultrasonic welding.

The mechanical and electrically conductive connection of the contact element formed as a press-in contact is particularly preferably established by means of press-in technology in at least one contact point of the circuit carrier formed as a contact opening.

### BRIEF DESCRIPTION OF THE DRAWINGS

Further preferred embodiments will emerge from the following description of an exemplary embodiment on the basis of drawings.

In schematic diagrams:

FIG. 1 shows an exemplary embodiment of the arrangement and contacting according to the invention of an electronic component on the basis of the example of a current-compensated choke coil, and

FIGS. 2a-2b show examples for electronic components provided for the arrangement and contacting.

### DETAILED DESCRIPTION OF THE PREFERRED EMBODIMENTS

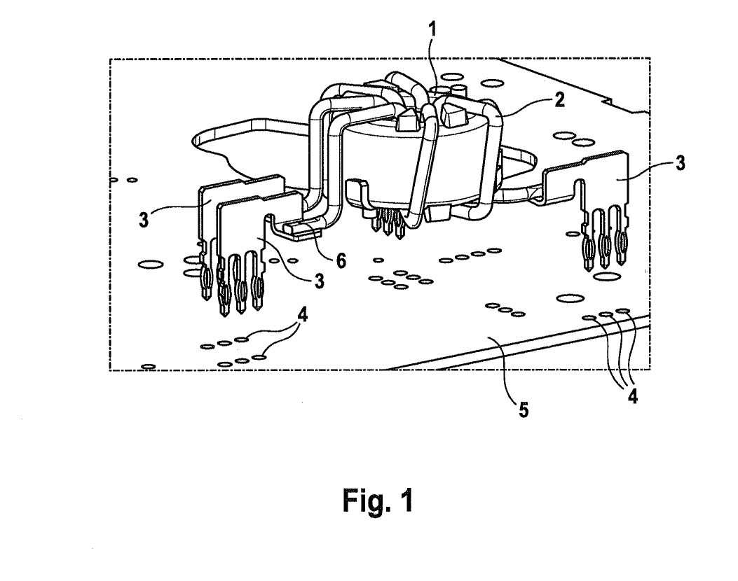

FIG. 1 shows an exemplary embodiment of the arrangement and contacting according to the invention of an electronic component, having a relatively large wire diameter, on a circuit carrier 5 on the basis of the example of a current-compensated choke coil 1. In accordance with the example the choke coil 1 serves to confine interference in a motor vehicle control unit, which interference, introduced for example via an on-board motor vehicle power supply system, can influence the electronics of the control unit.

The choke coil 1 here comprises at least one electrical conductor 2, the ends 6 of which and/or regions of which are connected electrically and mechanically to press-in contacts 3, as are described generically for example in DE 10 2009 025 113 A1, which is incorporated by reference.

The arrangement formed of choke coil 1 and press-in contacts 3 is shown here before the press-in zones of the press-in contacts 3 have been pressed into the contact openings 4 of the circuit carrier 5. Once the press-in zones of the press-in contacts 3 have been pressed into the contact openings 4, a mechanical fixing of the choke coil 1 on the circuit carrier 5 is provided as well as an electrically functional attachment. The electrical and mechanical connection of the electrical conductor 2 to the press-in contacts 3 is established in accordance with the invention preferably by means of ultrasonic welding.

In the case of ultrasonic welding the joining partners, in contrast to many other welding methods, are not heated to their melting point. The connection of two or more elements to be welded is instead established by an intermetallic connection, whereby the heat input into the weld metal and the thermal distortion are low. The press-in contacts 3 can thus be positioned precisely during the assembly process so as to be able to carry out the press-in process accordingly.

The established connection between the conductor 2 and press-in contact 3 does not only fix these mechanically, but additionally also provides electrical contact, of which the electrical transition resistance should be as low as possible. This requirement can be met in particular by contact produced by means of ultrasonic welding. Furthermore, the necessary requirements of the surfaces of the welding partners are only low, which eradicates the need for complex pre-treatments.

The dimensioning or design specification of the press-in contacts 3, in accordance with the exemplary embodiment of FIG. 1, are such that the choke coil 1 is distanced from the circuit carrier 5 in such a way that further electrical components (not illustrated), in particular SMD components, on the circuit carrier 5 can be provided in the region between the choke coil 1 and circuit carrier 5.

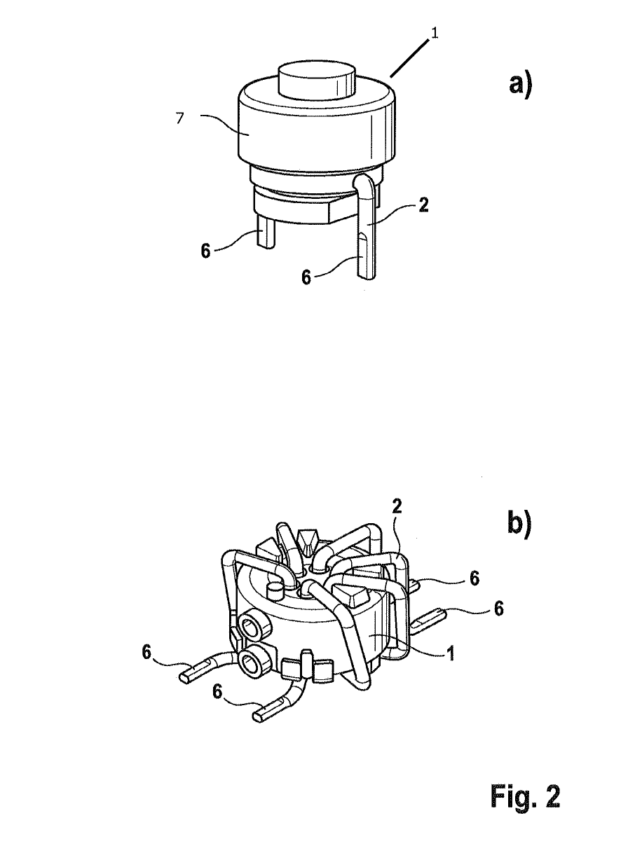

FIG. 2a) shows a further electronic component on the basis of the example of a ferrite rod core coil 7, whereas in FIG. 2b) the choke coil 1 is illustrated again separately. Substantially like elements have been provided with like reference signs in the figures.

1. An electronic control unit, of a motor vehicle brake system, comprising:
at least one circuit carrier for electronic components,
wherein at least one electric component has at least one electrical conductor,
wherein the electrical conductor of the electronic component is connected to at least one contact element mechanically and in an electrically conductive manner and the contact element is connected to at least one contact point of the circuit carrier mechanically and in an electrically conductive manner, wherein at least the mechanical and electrically conductive connection of the electrical conductor to the contact element is a connection established by ultrasonic welding.

2. The electronic control unit as claimed in claim 1, wherein the contact element and/or the electrical conductor of the electronic component are embodied such that the electronic component is distanced from the circuit carrier in such a way that further electronic components, can be arranged in a region between the circuit carrier and the electronic component.

3. The electronic control unit as claimed in claim 1, wherein the contact element is formed as a press-in contact, which comprises at least one press-in region, which is pressed into at least one contact point of the circuit carrier formed as a contact opening.

4. A method for arranging at least one electronic component on and electrically connecting said at least one electronic component to a circuit carrier of an electronic control unit, for a motor vehicle brake system, the method comprising:
connecting at least one electrical conductor comprised by the electronic component to at least one contact element mechanically and in an electrically conductive manner; and
connecting the contact element to at least one contact point of the circuit carrier mechanically and in an electrically conductive manner,
wherein at least the mechanical and electrically conductive connection of the electrical conductor to the contact element is established by ultrasonic welding.

5. The method as claimed in claim 4, wherein the mechanical and electrically conductive connection of the contact element formed as a press-in contact is established by press-in technology in at least one contact point of the circuit carrier formed as a contact opening.

6. The electronic control unit as claimed in claim 2, wherein the contact element is formed as a press-in contact, which comprises at least one press-in region, which is pressed into at least one contact point of the circuit carrier formed as a contact opening.
